(19) United States
(12) Patent Application Publication
(10) Pub. No.: US 2026/0235663 A1
(43) Pub. Date: Aug. 13, 2026

(54) THERMAL PREDICTION AND REGULATION DURING INTEGRATED CIRCUIT TESTING

(71) Applicant: ADVANTEST CORPORATION, Tokyo (JP)

(72) Inventors: Frank Christian MIELKE, Willich (DE); Jürgen SANG, Renningen (DE); Matthias SAUER, Böblingen (DE); Nadar Nasser ABAZARNIA, Chandler, AZ (US)

(21) Appl. No.: 19/340,752

(22) Filed: Sep. 25, 2025

Related U.S. Application Data
(60) Provisional application No. 63/755,975, filed on Feb. 7, 2025.

(51) Int. Cl. G01R 31/28

(52) U.S. Cl. CPC G01R 31/2874

(57) ABSTRACT

One embodiment of the present invention sets forth a technique for performing integrated circuit testing. The technique includes generating one or more temperature predictions for an area of interest within an integrated circuit based on sensor data associated with the integrated circuit. The technique also includes determining, based on the one or more temperature predictions and one or more control properties associated with the integrated circuit, one or more control parameters associated with a test of the integrated circuit. The technique further includes causing the test of the integrated circuit to be performed based on the one or more control parameters.

### CROSS-REFERENCE TO RELATED APPLICATIONS

This application claims the benefit of the U.S. Provisional Application titled "Thermal Prediction and Regulation During Integrated Circuit Testing," filed on February 7, 2025, and having Serial No. 63/755,975. The subject matter of this application is hereby incorporated herein by reference in its entirety.

### BACKGROUND

### Field of the Various Embodiments

The present invention relates generally to electronics and integrated circuit testing and, more specifically, to thermal prediction and regulation during integrated circuit testing.

### Description of the Related Art

Integrated circuit (IC) testing commonly involves a series of tests that verify the functionality, performance, and reliability of an IC and/or semiconductor device. These tests are commonly performed to detect different types of defects and/or issues associated with the IC and/or different stages of production involving the IC.

A typical sequence of IC tests may include sort testing that verifies conductivity, leakage, and/or other electrical properties of dies on a wafer. Dies that pass sort testing are separated and packaged, and burn-in testing of each packaged die may be performed to stress the packaged die at or above the corresponding rated operating and/or temperatures to identify and remove devices associated with early-life failures. Each packaged die may also, or instead, be subject to a final test that assesses the power consumption, frequency, input/output (I/O) functionality, and/or other characteristics of the packaged die and verifies that the packaged die meets design specifications for integrity and reliability. Multiple dies may also, or instead, be assembled into an integrated system (e.g., a system-on-chip (SoC), system in package (SiP), multi-chip module (MCM), printed circuit board (PCB), etc.), and system-level testing may be performed to validate the correct operation of the integrated system in intended end-use applications.

During IC testing, an IC may be exposed to a wide range of conditions that cause temperatures within the IC to increase and/or fluctuate. To prevent the temperatures from reaching unsafe and/or damaging levels, a thermal system is commonly used to monitor and/or regulate the temperatures as the IC is tested. For example, a conventional thermal system may compare temperature measurements from individual temperature sensors, average temperature values (e.g., from multiple temperature sensors), power consumption, and/or other values measured or determined during a given IC test with one or more preset limits. When a preset limit is reached or exceeded by a corresponding temperature measurement or value, the thermal system may generate control signals to heat or cool the IC.

However, increases in the capabilities and integration of modern ICs over time have led to more complex test requirements and corresponding difficulties in controlling the temperatures of the ICs. More specifically, increases in the power consumption of ICs over time have resulted in corresponding increases in the risk of thermal damage to the ICs. At the same time, certain regions within complex ICs, packages, and/or integrated systems of ICs may experience temperatures that are vastly different from those measured by temperature sensors. Further, the thermal system may fail to respond in a timely manner to sudden changes in heat generation during events such as (but not limited to) rapid transitions between test phases and/or operating modes. This inability to monitor temperatures throughout an IC and/or compensate for sudden changes in heat generation during an IC test may cause the temperatures to reach and/or exceed corresponding limits and result in damage to or destruction of the IC.

As the foregoing illustrates, what is needed in the art are more effective techniques for determining and regulating temperatures in ICs during testing of the ICs.

### SUMMARY

One embodiment of the present invention sets forth a technique for performing integrated circuit testing. The technique includes generating one or more temperature predictions for an area of interest within an integrated circuit based on sensor data associated with the integrated circuit. The technique also includes determining, based on the one or more temperature predictions and one or more control properties associated with the integrated circuit, one or more control parameters associated with a test of the integrated circuit. The technique further includes causing the test of the integrated circuit to be performed based on the one or more control parameters.

One technical advantage of the disclosed techniques relative to the prior art is the ability to monitor and control temperatures at various areas of interest (AOIs) within an IC in an accurate and timely manner. Consequently, the disclosed techniques may avoid and/or mitigate thermal damage and/or destruction that stem from limited monitoring of temperatures by temperature sensors and/or the inability to react quickly to sudden changes in heat generation during IC testing. These technical advantages provide one or more technological improvements over prior art approaches.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram of a computing system configured to implement one or more aspects of the various embodiments.

FIG. 2 is a more detailed illustration of the training engine and execution engine of FIG. 1, according to various embodiments.

FIG. 3 illustrates example training data for the machine learning models of FIG. 2, according to various embodiments.

FIG. 4 illustrates an example system for performing integrated circuit (IC) testing, according to various embodiments.

FIG. 5 is a flow diagram of method steps for performing IC testing, according to various embodiments.

### DETAILED DESCRIPTION OF EXEMPLARY EMBODIMENTS

In the following description, numerous specific details are set forth to provide a more thorough understanding of the embodiments of the present invention. However, it will be apparent to one of skill in the art that the embodiments of the present invention may be practiced without one or more of these specific details.

### Overview

As discussed above, a conventional thermal system may regulate temperatures within an IC during testing of the IC by comparing temperature measurements from individual temperature sensors, average temperature values (e.g., from multiple temperature sensors), power consumption, and/or other values measured or determined during a given IC test with one or more preset limits. When a preset limit is reached or exceeded during a test, the thermal system may generate control signals to heat or cool a corresponding IC.

However, certain regions within complex ICs, packages, and/or integrated systems of ICs may experience temperatures that are vastly different from those measured by temperature sensors. Further, the thermal system may fail to respond in a timely manner to sudden changes in heat generation during events such as (but not limited to) rapid transitions between test phases and/or operating modes. This inability to monitor temperatures throughout an IC and/or compensate for sudden changes in heat generation during an IC test may cause the temperatures to reach and/or exceed corresponding limits and result in damage to or destruction of the IC.

To address the above limitations, the disclosed techniques predict and regulate temperatures for various areas of interest (AOIs) within an IC during testing of the IC. Each AOI may include (but is not limited to) a two-dimensional (2D) and/or three-dimensional (3D) grid cell, functional block, arbitrarily shaped area, and/or another type of region or zone within the IC.

More specifically, the disclosed techniques use machine learning models, physics-based models, simulations, and/or other techniques to generate temperature predictions for each AOI within an IC based on sensor data, test parameters, and/or other inputs collected during testing of the IC. Each temperature prediction may represent a "real silicon temperature" at a corresponding AOI instead of temperatures measured by one or more temperature sensors that that are positioned outside of and/or at various distances from the AOI.

The temperature predictions are also used with the machine learning models, physics-based models, simulations, and/or other techniques to generate control parameters that are used to regulate the temperatures within the AOIs during testing of the IC. These control parameters may include (but are not limited to) target temperatures, thermal control signals for thermal systems, control signals that adjust the pace of testing, and/or control signals that start or stop testing operations. The control parameters may be determined based on the temperature predictions and/or control properties associated with the test, such as (but not limited to) temperature limits, temperature slopes, power slopes, safety offsets, and/or other values that characterize the progress and/or conditions of the test.

The temperature predictions and/or control parameters may be generated by an independent computing unit (e.g., computer-on-module (COM), single-board computer, etc.) that operates separately from and concurrently with a thermal system that performs thermal control of the IC using the control parameters and a test system (e.g., automated test equipment (ATE), test program, etc.) that performs testing of the IC. This independent computing unit acts as an intermediate control point that decouples the test system and thermal system from one another while allowing the operation of each system to influence the operation of the other system. The independent computing unit also allows the thermal system, test system, and/or other components to access temperatures associated with the IC in an “on-demand” basis (e.g., without any “blind periods” in which the temperature sensors are not available).

Temperature prediction and control may additionally be performed across different stages of IC testing, such as (but not limited to) wafer sort testing, die-level testing, burn-in testing, final testing, and/or system-level testing. Data collected during earlier testing stages may be tracked and used to perform thermal prediction and control in later stages for the same IC. This data may also, or instead, be used to design, evaluate, and/or modify die layouts and/or packages involving the IC, test configurations for the tests, and/or other parameters associated with testing and/or using the IC.

One technical advantage of the disclosed techniques relative to the prior art is the ability to monitor and control temperatures at various AOIs within an IC in an accurate and timely manner. Consequently, the disclosed techniques may avoid and/or mitigate thermal damage and/or destruction that stems from the limited monitoring of temperatures by temperature sensors and/or the inability to react quickly to sudden changes in heat generation during IC testing. Additionally, by incorporating thermal data collected during earlier testing stages into thermal prediction and regulation during subsequent testing stages involving the same IC, the disclosed techniques may improve the design and/or thermal management of complex ICs, packages, and/or integrated systems of multiple components with different thermal responses. These technical advantages provide one or more technological improvements over prior art approaches.

### System Overview

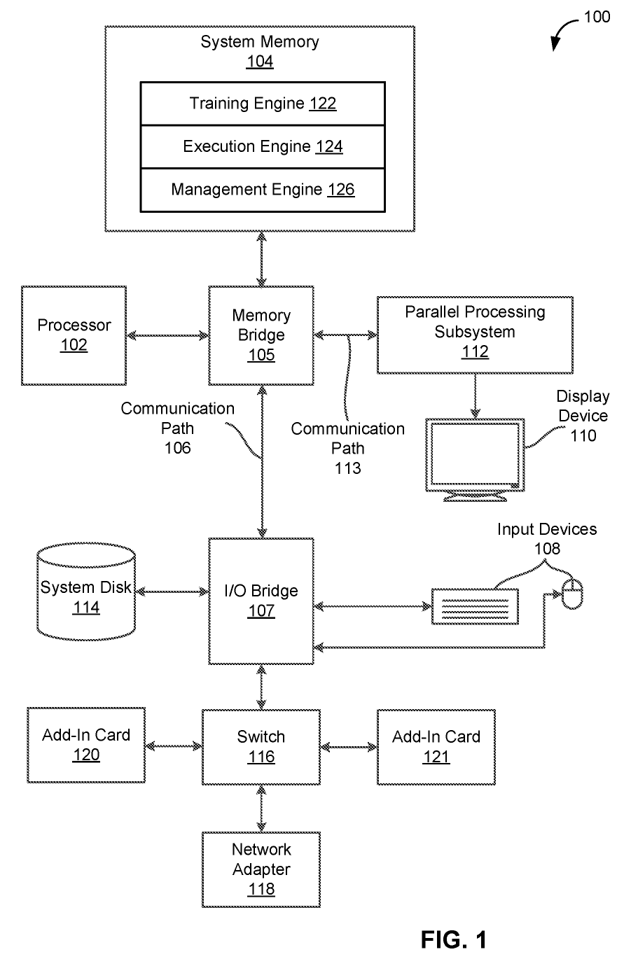

FIG. 1 is a block diagram of a computing system 100 configured to implement one or more aspects of the various embodiments. In at least one embodiment, computing system 100 may include any type of computing device, including, without limitation, a server machine, a server platform, a desktop machine, a laptop machine, a hand-held/mobile device, a digital kiosk, an in-vehicle infotainment system, a smart speaker or display, a television, and/or a wearable device. In at least one embodiment, computing system 100 is a server machine operating in a data center or a cloud computing environment that provides scalable computing resources as a service over a network.

In various embodiments, computing system 100 includes, without limitation, one or more processors 102 and one or more memories 104 coupled to a parallel processing subsystem 112 via a memory bridge 105 and a communication path 113. Memory bridge 105 is further coupled to an I/O (input/output) bridge 107 via a communication path 106, and I/O bridge 107 is, in turn, coupled to a switch 116.

In one embodiment, I/O bridge 107 is configured to receive user input information from optional input devices 108, such as (but not limited to) a keyboard, mouse, touch screen, sensor data analysis (e.g., evaluating gestures, speech, or other information about one or more uses in a field of view or sensory field of one or more sensors), a VR/MR/AR headset, a gesture recognition system, a steering wheel, mechanical, digital, or touch sensitive buttons or input components, and/or a microphone, and forward the input information to processor(s) 102 for processing. In at least one embodiment, computing system 100 may be a server machine in a cloud computing environment. In such embodiments, computing system 100 may omit input devices 108 and receive equivalent input information as commands (e.g., responsive to one or more inputs from a remote computing device) and/or messages transmitted over a network and received via the network adapter 118. In at least one embodiment, switch 116 is configured to provide connections between I/O bridge 107 and other components of computing system 100, such as a network adapter 118 and various add in cards 120 and 121.

In at least one embodiment, I/O bridge 107 is coupled to a system disk 114 that may be configured to store content and applications and data for use by processor(s) 102 and parallel processing subsystem 112. In one embodiment, system disk 114 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, may be connected to I/O bridge 107 as well.

In various embodiments, memory bridge 105 may be a Northbridge chip, and I/O bridge 107 may be a Southbridge chip. In addition, communication paths 106 and 113, as well as other communication paths within computing system 100, may be implemented using any technically suitable protocols, including, without limitation, AGP (Accelerated Graphics Port), HyperTransport, or any other bus or point to point communication protocol known in the art.

In at least one embodiment, parallel processing subsystem 112 includes a graphics subsystem that delivers pixels to an optional display device 110 that may be any conventional cathode ray tube, liquid crystal display, light-emitting diode display, and/or the like. In such embodiments, parallel processing subsystem 112 may incorporate circuitry optimized for graphics and video processing, including, for example, video output circuitry. Such circuitry may be incorporated across one or more parallel processing units (PPUs), also referred to herein as parallel processors, included within the parallel processing subsystem 112.

In at least one embodiment, parallel processing subsystem 112 incorporates circuitry optimized (e.g., that undergoes optimization) for general purpose and/or compute processing. Again, such circuitry may be incorporated across one or more PPUs included within parallel processing subsystem 112 that are configured to perform such general purpose and/or compute operations. In yet other embodiments, the one or more PPUs included within parallel processing subsystem 112 may be configured to perform graphics processing, general purpose processing, and/or compute processing operations. Memor(ies) 104 include at least one device driver configured to manage the processing operations of the one or more PPUs within parallel processing subsystem 112. In addition, memor(ies) 104 include instructions implementing a training engine 122 and an execution engine 124, which can be executed by processor(s) and/or parallel processing subsystem 112.

In various embodiments, parallel processing subsystem 112 may be integrated with one or more of the other elements of FIG. 1 to form a single system. For example, parallel processing subsystem 112 may be integrated with processor(s) 102 and other connection circuitry on a single chip to form a system on a chip (SoC).

Processor(s) 102 may include any suitable processor implemented as a central processing unit (CPU), a graphics processing unit (GPU), an application-specific integrated circuit (ASIC), a field programmable gate array (FPGA), an artificial intelligence (AI) accelerator, a deep learning accelerator (DLA), a parallel processing unit (PPU), a data processing unit (DPU), a vector or vision processing unit (VPU), a programmable vision accelerator (PVA) (which may include one or more VPUs, pixel processing engines (PPEs), and/or direct memory access (DMA) systems), any other type of processing unit, or a combination of different processing units, such as a CPU(s) configured to operate in conjunction with a GPU(s). In general, processor(s) 102 may include any technically feasible hardware unit capable of processing data and/or executing software applications. Further, in the context of this disclosure, the computing elements shown in computing system 100 may correspond to a physical computing system (e.g., a system in a data center or a machine) and/or may correspond to a virtual computing instance executing within a computing cloud.

In at least one embodiment, processor(s) 102 issue commands that control the operation of PPUs. In at least one embodiment, communication path 113 is a Peripheral Component Interconnect Express (PCIe) link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of processors 102, and the number of parallel processing subsystems 112, may be modified as desired. For example, in at least one embodiment, memor(ies) 104 may be connected to processor(s) 102 directly rather than through memory bridge 105, and other devices may communicate with memor(ies) 104 via memory bridge 105 and processors 102. In other embodiments, parallel processing subsystem 112 may be connected to I/O bridge 107 or directly to processor(s) 102, rather than to memory bridge 105. In still other embodiments, I/O bridge 107 and memory bridge 105 may be integrated into a single chip instead of existing as one or more discrete devices. In certain embodiments, one or more components shown in FIG. 1 may not be present. For example, switch 116 may be eliminated, and network adapter 118 and add in cards 120, 121 would connect directly to I/O bridge 107. Further, in certain embodiments, one or more components shown in FIG. 1 may be implemented as virtualized resources in a virtual computing environment, such as a cloud computing environment.

In one or more embodiments, computer system 100 is configured to execute a training engine 122, an execution engine 124, and a management engine 126 that reside in system memory 104. Training engine 122, execution engine 124, and management engine 126 may be stored in system disk 114 and/or other storage and loaded into system memory 104 when executed.

In some embodiments, training engine 122, execution engine 124, and management engine 126 include functionality to perform thermal prediction and regulation during integrated circuit (IC) testing. More specifically, training engine 122 and execution engine 124 may use machine learning models, physics-based models, simulations, experiments, and/or other techniques to generate temperature predictions for various areas of interest (AOIs) within a given IC. Training engine 122 and execution engine 124 may also use the same techniques and/or different techniques to generate control parameters and/or control signals that are used to regulate temperatures within the AOIs during testing of the IC. The temperature predictions, control parameters, and/or control signals may be generated and/or updated within a control loop, so that temperatures experienced by the AOIs can be adjusted before the temperatures reach levels that can damage the IC.

Management engine 126 may generate, store, and/or update records of temperature predictions, control parameters, control signals, test results, die layouts, test configurations, and/or other data used in various stages of IC testing, including (but not limited to) wafer sort, die-level handling, burn-in testing, final testing, and/or system-level testing. Management engine 126 may additionally use data collected during earlier testing stages to perform thermal prediction and/or regulation of the same ICs in later testing stages. The operation of training engine 122, execution engine 124, and management engine 126 is described in further detail below.

### Thermal Prediction and Regulation During Integrated Circuit Training

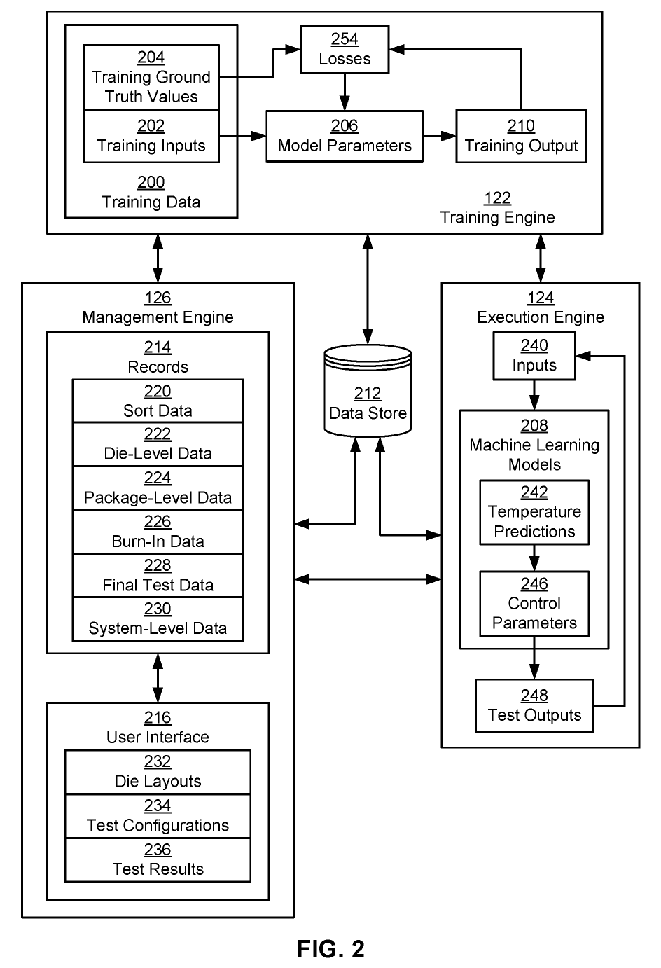

FIG. 2 is a more detailed illustration of training engine 122, execution engine 124, and management engine 126 of FIG. 1, according to various embodiments. As mentioned above, training engine 122, execution engine 124, and management engine 126 include functionality to perform thermal prediction and regulation during IC testing. Each of these components is described in further detail below.

In one or more embodiments, thermal regulation and control is performed during a test of a given IC using one or more machine learning models 208. More specifically, one or more machine learning models 208 may generate temperature predictions 242 for various AOIs on an IC based on inputs 240 associated with the test and/or IC. Each temperature prediction represents a "real silicon temperature" at a corresponding AOI instead of temperatures measured by one or more temperature sensors that that are positioned outside of and/or at various distances from the AOI. Consequently, temperature predictions 242 may be used to assess thermal responses and/or characteristics at locations within the IC that cannot be directly measured using the temperature sensor(s).

The same machine learning models 208 and/or one or more additional machine learning models 208 may additionally generate control parameters 246 that are used to regulate temperatures within the AOIs during the test based on temperature predictions 242 and/or other inputs 240. For example, one or more machine learning models 208 may be used to generate target temperatures, temperature limits, thermal control signals, signals for adapting test pacing and/or stopping the test, and/or other values that can be used to control and/or regulate temperature within the IC and/or individual AOIs in the IC.

In one or more embodiments, an AOI corresponds to a region within an IC. For example, the IC may be divided into two-dimensional (2D) and/or three-dimensional (3D) grid cells corresponding to different AOIs. In another example, each AOI may be defined as a region with an arbitrary shape and/or size within the IC. In a third example, a given AOI may correspond to a functional block, layer, and/or another discrete portion of the IC.

Machine learning models 208 may include (but are not limited to) multilayer perceptrons, recurrent neural networks (RNNs), convolutional neural networks (CNNs), transformer neural networks, regression models, tree-based models, time series models, support vector regression (SVR) models, and/or other types of models that are capable of processing numeric and/or time series data. The prediction generated by a given machine learning model may be supplemented and/or replaced with a prediction generated via one or more other techniques, such as (but is not limited to) a physics-based model, control loop, simulation, and/or experiment. For example, multiple temperature predictions generated by machine learning models 208, physics-based models, control loops, simulations, and/or experiments for a given AOI may be combined into an overall temperature prediction for the AOI via an average, weighted combination, an additional machine learning model, and/or another aggregation technique.

Training engine 122 trains machine learning models 208 to generate temperature predictions 242 and/or control parameters 246 associated with the AOIs. As shown in FIG. 2, training engine 122 uses training data 200 that includes training inputs 202 and training ground truth values 204 to update model parameters 206 of machine learning models 208. For example, training engine 122 may generate and/or retrieve training data 200 via one or more simulations, experiments, physics-based models, measurements, historical tests of the IC, and/or other techniques. Training engine 122 may input training inputs 202 associated with one or more AOIs into one or more machine learning models 208. Training engine 122 may use model parameters 206 of the machine learning model(s) to process training inputs 202 and obtain training output 210 that includes temperature predictions 242 and/or control parameters 246 for the AOI(s) from one or more layers, blocks, and/or components of the machine learning model(s). Training engine may compute one or more losses 254 (e.g., mean squared error, mean absolute error, Huber loss, etc.) between training output 210 and the corresponding training ground truth values 204 in training data. Training engine 122 may then use a training technique (e.g., gradient descent and backpropagation) to iteratively update model parameters 206 of the machine learning model(s) in a way that reduces losses 254.

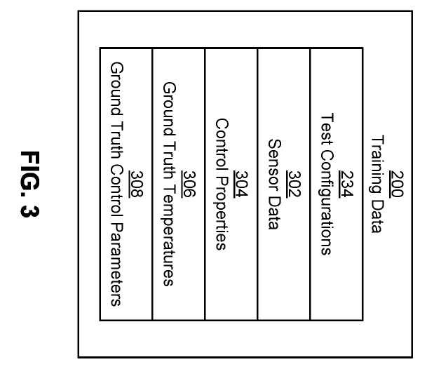

FIG. 3 illustrates example training data 200 for machine learning models 208 of FIG. 2, according to various embodiments. As shown in FIG. 3, training data 200 may include (but is not limited to) test configurations 234, sensor data 302, control properties 304, ground truth temperatures 306, and/or ground truth control parameters 308 associated with a given test and/or IC.

Each of test configurations 234 includes information related to a certain type of test of a given IC. For example, a test configuration may include (but are not limited to) one or more target temperatures, one or more temperature limits (e.g., test-based temperature limits, damage limits, damage “pre-limits” that cause a test program to be paused until a safe temperature is reached, etc.), AOIs associated with the test, measurements to be made during the test, test steps to be performed during the test, equipment used in the test, and/or other values that characterize the test.

Sensor data 302 includes real and/or simulated measurements of attributes associated with a given IC. These attributes may include (but are not limited to) temperature (e.g., at locations of one or more sensors on and/or around the IC), power (e.g., via a power monitor), aging, current, voltage, voltage drop, and/or other values that characterize the state of the IC.

Control properties 304 include information related to the progress of a given test and/or the thermal behavior of the IC during the test. For example, control properties 304 may include (but are not limited to) a sum of temperature values above and below a target temperature and/or limit, a temperature slope, a power slope, an increase or decrease in a temperature or power slope, a minimum and/or maximum deviation of a temperature (or another attribute) from a corresponding target and/or limit, a warning and/or alert related to a damage limit (or another type of event), a test-continue signal, one or more safety offsets related to a target temperature, a distribution of power values per AOI, and/or anomalous/outlier values for temperature, power, and/or another attribute.

Ground truth temperatures 306 include temperature values for individual AOIs in the IC. For example, each ground truth temperature may be generated by a simulation, experiment, physics-based model, measurement, and/or another technique. Each ground truth temperature may also be associated with a corresponding test configuration, set of sensor data 302, and/or control properties 304, so that the test configuration, sensor data 302, and/or control properties 304 act as features that can be used by a machine learning model to predict the ground truth temperature.

Ground truth control parameters 308 include values related to control and/or regulation of temperature within an IC and/or individual AOIs in the IC. For example, ground truth control parameters 308 may include (but are not limited to) a target temperature associated with a temperature sensor in and/or around the IC, a target temperature associated with a given AOI in the IC, another type of thermal control signal that is used to control a thermal system that regulates the temperature of the IC and/or one or more portions of the IC, and/or any other type of input that can be used to control the thermal conditions of the IC. Ground truth control parameters 308 may also, or instead, include control inputs related to execution of the test, such as (but not limited to) signals related to adapting the pace of the test (e.g., enabling cooldown and/or temperature stabilization) and/or stopping the test (e.g., to prevent damage to the IC). Ground truth control parameters 308 may also, or instead, include quality improvements, statistics, root cause analysis for failures, and/or other information and/or test results that can be used to assess the quality of the IC and/or logged for subsequent use. A given set of ground truth control parameters 308 may be associated with a test configuration, set of sensor data 302, control properties 304, and/or set of ground truth temperatures 306, so that the test configuration, sensor data 302, control properties 304, and/or ground truth temperatures 306 act as features that can be used by a machine learning model to predict these ground truth control parameters 308.

In some embodiments, test configurations 234, sensor data 302, and/or control properties 304 are used as training inputs 202 that are processed by a given machine learning model to generate corresponding training output 210. These training inputs 202 may additionally be associated with training ground truth values 204 that include ground truth temperatures 306, ground truth control parameters 308, and/or other values to be predicted from training inputs 202. For example, a given test configuration, set of sensor data 302, and/or set of control properties 304 may be input into and/or used to select a machine learning model that is trained to predict one or more corresponding ground truth temperatures 306. In another example, a given test configuration, set of sensor data 302, set of control properties 304, and/or ground truth temperatures 306 may be input into and/or used to select a machine learning model that is trained to predict one or more corresponding ground truth control parameters 308.

In one or more embodiments, training engine 122 trains machine learning models 208 over one or more training stages to optimize machine learning models 208 based on various losses 254, types of training output 210, performance characteristics, and/or other objectives or factors. For example, training engine 122 may train a first set of one or more machine learning models 208 to predict ground truth temperatures 306 based on corresponding test configurations 234, sensor data 302, and/or control properties 304. Training engine 122 may separately train a second set of one or more machine learning models 208 to predict ground truth control parameters 308 based on corresponding test configurations 234, sensor data 302, control properties 304, and/or ground truth temperatures 306. Training engine 122 may also, or instead, train both sets of machine learning models 208 in an end-to-end fashion, so that control parameters 246 generated by the second set of machine learning models 208 are optimized based on temperature predictions 242 generated by the first set of machine learning models 208. Training engine 122 may also, or instead, train individual machine learning models 208 to generate both temperature predictions 242 and control parameters 246 for different ICs and/or AOIs within an IC.

Returning to the discussion of FIG. 2, after training of machine learning models 208 is complete, training engine 122 may store parameters and/or other representations of the trained machine learning models 208 in a database, cloud storage, distributed filesystem, and/or another type of data store 212 for subsequent retrieval and use.

Execution engine 124 uses the trained machine learning models 208 from training engine 122 and/or data store 212, physics-based models, simulations, experiments, control loops, and/or other techniques to generate temperature predictions 242 and control parameters 246 that are used to control temperatures and/or other parameters of various IC tests. More specifically, execution engine 124 may collect inputs 240 that include (but are not limited to) temperatures, power, aging, current, voltage, voltage drop, and/or other types of sensor data that characterize the state of an IC. The inputs 240 may further include target temperatures, temperature limits, AOIs, measurements to be made, test steps, equipment used, and/or other test configuration attributes that characterize a given test of the IC. The inputs 240 may also include a sum of temperature values above and below a target temperature and/or limit, a temperature slope, a power slope, a change in temperature or power slope, a minimum and/or maximum deviation of a temperature from a corresponding target and/or limit, a warning and/or alert related to a damage limit, a test-continue signal, one or more safety offsets related to a target temperature, a distribution of power values per AOI, anomalous/outlier attribute values, and/or other control properties that characterize the progress of the test.

Execution engine 124 may use machine learning models 208 and/or other techniques to generate temperature predictions 242 for the AOIs based on inputs 240. Execution engine 124 may additionally use machine learning models 208 and/or other techniques to generate control parameters 246 that are used to regulate temperatures in the AOIs and/or IC based on inputs 240 and/or temperature predictions 242. Execution engine 124 may additionally generate test outputs 248 that include temperature predictions 242; control parameters 246; sensor data that is collected before, during, and/or after applying a given set of control parameters 246 to the IC; control properties; test steps; and/or other information associated with temperature predictions 242 and/or control parameters 246. These test outputs 248 may be stored in data store 212 and/or provided as additional inputs 240 that are used by machine learning models 208 and/or other techniques to generate new temperature predictions 242 and/or control parameters 246 for subsequent time steps in the test.

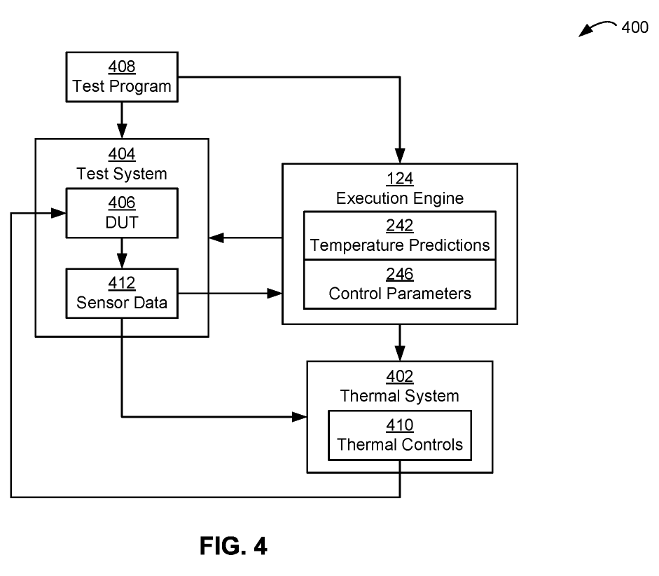

In one or more embodiments, execution engine 124 runs on an independent computing unit that is separate from a test system used to conduct an IC test and a thermal system that is used to regulate temperature on an IC subject to the IC test. As described in further detail below with respect to FIG. 4, the independent computing unit may act as an intermediate control point that decouples testing of the IC by the test system from thermal control of the IC by the thermal system while allowing the test system and thermal system to influence one another during the test.

FIG. 4 illustrates an example system 400 for performing IC testing, according to various embodiments. As shown in FIG. 4, system 400 includes a thermal system 402, a test system 404, and execution engine 124.

Test system 404 includes automatic test equipment (ATE) that performs testing of a device under test (DUT) 406 (e.g., an IC) according to a sequence of test steps defined in a test program 408. For example, test program 408 may include commands, control signals, and/or instructions that are executed by test system 404 to perform the test steps. While the test steps are performed, sensor data 412 that includes (but is not limited to) temperature measurements, power consumption values, voltage readings, current measurements, and/or other attributes that characterize the operational state of the IC may be collected by sensors integrated into test system 404.

Execution engine 124 receives sensor data 412 from DUT 406, details associated with a current test step from test program 408, and/or other inputs 240 associated with DUT 406 and/or the test. Execution engine 124 uses trained machine learning models 208, physics-based models, simulations, and/or other techniques to process these inputs 240 and generate temperature predictions 242 for various AOIs within DUT 406.

Execution engine 124 also generates control parameters 246 based on temperature predictions 242, control properties associated with the test, and/or other information associated with the test. Control parameters 246 may include target temperatures for thermal regulation, thermal control signals, adjustments to test steps or test operations, and/or other parameters that influence the thermal conditions of DUT 406.

Thermal system 402 receives control parameters 246 from execution engine 124 and use these control parameters 246 to control the temperature of DUT 406. For example, thermal system 402 may include heating elements, cooling systems, temperature controllers, and/or other thermal controls 410 that can be used to regulate the thermal environment of DUT 406.

As shown in FIG. 4, thermal system 402 may receive sensor data 412 directly from test system 404 and use sensor data 412 to adjust thermal controls 410 separately from control parameters 246 received from execution engine 124. Similarly, test system 404 may receive values of temperature predictions 242 and/or control parameters 246 from execution engine 124 and/or thermal controls 410 from thermal system 402. Test system 404 may use the received values to adjust the execution of test steps specified in test program 408 (e.g., by adjusting the pacing of the test, stopping the test, performing and/or omitting certain test steps, etc.).

As mentioned above, execution engine 124 may execute on an independent computing unit (e.g., computer-on-module (COM), single-board computer, etc.) that is separate from test system 404 and thermal system 402. This independent computing unit acts as an intermediate control point that decouples testing of DUT 406 by test system 404 from thermal regulation of DUT 406 by thermal system 402. At the same time, temperature predictions 242 and/or control parameters 246 generated by execution engine 124 are generated based on test content associated with (i) test program 408 and/or test system 404 and (ii) thermal sensor data 412 that reflects the effect of thermal controls 410 on temperatures in DUT 406. This allows test system 404 and thermal system 402 to influence one another during the test. Further, because execution engine 124 generates temperature predictions 242 and/or control parameters 246 at a rate that is independent of the rate at which sensor data 412 is collected, thermal system 402, test system 404, and/or other components can access thermal data (e.g., temperature predictions 242, control parameters 246, etc.) associated with DUT 406 in an “on-demand” basis (e.g., in a way that avoids “blind periods” during which temperature and/or other sensors are not available to generate sensor data 412).

Returning to the discussion of FIG. 2, management engine 126 generates and updates records 214 that are used to track test outputs 248 and/or other types of data or entities involved in testing of a given IC. These records 214 may be stored in data store 212 (e.g., in one or more database tables, files, etc.) and/or shared with training engine 122, execution engine 124, and/or other components involved in thermal prediction and regulation during IC tests.

As shown in FIG. 2, records 214 include sort data 220, die-level data 222, package-level data 224, burn-in data 226, final test data 228, and/or system-level data 230 collected during corresponding stages of IC testing. Sort data 220 may include conductivity, leakage current, voltage, frequency, thermal data, and/or data that is collected during wafer sort testing of a wafer. Consequently, sort data 220 may capture the thermal behavior of individual dies on the wafer before packaging.

Die-level data 222 may include data that is generated during die-level testing of individual dies after separation from a wafer and before packaging. For example, die-level data 222 may include temperature profiles, power dissipation patterns, thermal resistance values, and other thermal characteristics specific to each die. Die-level data 222 may also, or instead, include information related to die placement, orientation, physical properties, and/or other die attributes that influence thermal behavior during testing.

Package-level data 224 may include information that is collected after dies are assembled into packages. For example, package-level data 224 may include packaging materials, thermal interfaces, package geometry, and/or other attributes affect the thermal response of the IC. Package-level data 224 may also, or instead, include case temperatures, thermal resistance between junction and case, heat dissipation patterns, thermal coupling between multiple dies in multi-die packages, and/or other thermal characteristics of a given package.

Burn-in data 226 may include information that is collected during burn-in testing of packaged dies. For example, burn-in data 226 may include changes in temperature drift, power consumption changes, thermal stability metrics, and/or other thermal characteristics over time and/or under varying stress conditions. Burn-in data 226 may also, or instead, include information related to thermal cycling effects and temperature-dependent failure modes in the packaged dies.

Final test data 228 may include information that is collected during final testing of packaged dies. For example, final test data 228 may include temperature profiles associated with various operating modes, power states, and/or test conditions.

System-level data 230 may include information that is collected during system-level testing of multiple ICs that are integrated into larger systems. For example, system-level data 230 may capture thermal interactions between different components, system-level thermal management requirements, and/or thermal performance under various operating conditions and/or end-use applications. System-level data 230 may also, or instead, include information related to thermal coupling effects, heat spreading, and system-level thermal control strategies.

In some embodiments, sort data 220, die-level data 222, package-level data 224, burn-in data 226, final test data 228, and/or system-level data 230 include identifiers (e.g., test stage identifiers, IC identifiers, etc.), inputs 240, temperature predictions 242, control parameters 246, and/or test outputs 248 associated with the corresponding testing stages. Additionally, sort data 220, die-level data 222, package-level data 224, burn-in data 226, final test data 228, and/or system-level data 230 for a given IC may be stored in data store 212 and used by management engine 126 to improve testing and/or thermal regulation of the IC across the testing stages.

More specifically, management engine 126 may provide data collected during earlier testing stages as inputs 240 to machine learning models 208 and/or other components that generate temperature predictions 242, control parameters 246, and/or test outputs 248 in subsequent testing stages involving the same ICs and/or components. For example, management engine 126 may use sort data 220 and/or die-level data 222 for a given die as a set of baseline thermal characteristics that can be used to generate temperature predictions 242, control parameters 246, and/or thermal responses of the same die in subsequent testing stages. In another example, management engine 126 may use package-level data 224, burn-in data 226, and/or final test data 228 for a given package to inform system-level testing and/or thermal regulation of an integrated system that includes the package.

Management engine 126 may also, or instead, use sort data 220, die-level data 222, package-level data 224, burn-in data 226, final test data 228, and/or system-level data 230 in records 214 to generate and/or modify die layouts 232, test configurations 234, and/or test results 236 associated with a given IC. As shown in FIG. 2, management engine 126 may provide a user interface 216 that can be used to view, search for, modify, and/or otherwise access records 214. User interface 216 may also, or instead, be used to generate, view, and/or modify die layouts 232 in packages and/or integrated systems based on thermal responses of the corresponding dies (e.g., as represented by temperature predictions 242, control parameters 246, and/or other thermal information in sort data 220 and/or die-level data 222 associated with the dies). User interface 216 may also, or instead, be used to set and/or adjust thermal limits and/or other attributes of test configurations 234 for one or more testing stages based on thermal responses determined during previous testing stages involving the same IC. User interface 216 may also, or instead, be used to view and/or compare test results 236 for the same IC and/or different ICs across testing stages. Consequently, management engine 126 and/or user interface 216 may allow users and/or other entities involved in designing and/or testing wafers, dies, packages, integrated systems, and/or other IC-based systems or components to optimize various stages in the design and testing of the IC-based systems or components.

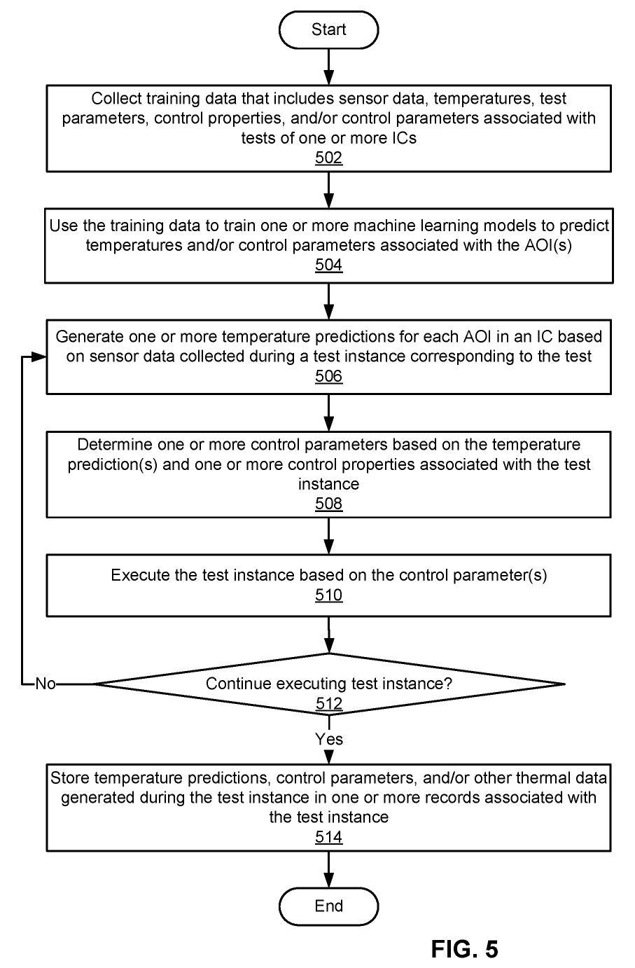

FIG. 5 is a flow diagram of method steps for performing integrated circuit testing, according to various embodiments. Although the method steps are described in conjunction with the systems of FIGS. 1-2 and 4, persons skilled in the art will understand that any system configured to perform some or all of the method steps in any order falls within the scope of the present disclosure.

As shown, in step 502, training engine 122 collects training data that includes sensor data, temperatures, test parameters, control properties, and/or control parameters associated with tests of one or more ICs. For example, training engine 122 may generate and/or retrieve the training data via one or more simulations, experiments, physics-based models, measurements, historical tests of the IC(s), and/or other techniques.

In step 504, training engine 122 uses the training data to train one or more machine learning models to predict temperatures and/or control parameters associated with one or more AOIs in the IC(s). For example, training engine 122 may train a first machine learning model to predict a temperature of an AOI within a given IC based on input that includes sensor data collected during a test of the IC. Training engine 122 may also, or instead, train a second machine learning model to predict a target temperature, thermal control signal, and/or another type of thermal control parameter associated with the AOI and/or IC based on predicted temperatures outputted by the first machine learning model (or via another technique) and/or control properties computed during a test of the IC.

In step 506, execution engine 124 generates one or more temperature predictions for each AOI in an IC based on sensor data collected during a test instance corresponding to the test. For example, execution engine 124 may run on an independent computing unit during execution of the test instance. As the sensor data is collected, execution engine 124 may use one or more machine learning models trained using steps 502 and 504 and/or other techniques to generate temperature predictions for each AOI on a periodic and/or continuous basis. When temperature predictions are to be generated for multiple AOIs on the IC and/or multiple ICs at the same time, execution engine 124 may generate the temperature predictions in parallel (e.g., on multiple processors, processor cores, etc.). Each temperature prediction may represent a “real silicon temperature” at a corresponding AOI instead of a temperature measured by a sensor that is potentially outside the AOI.

In some embodiments, execution engine 124 generates the temperature prediction(s) using additional information associated with the IC. For example, execution engine 124 may use additional machine learning models trained during steps 502 and 504, physics-based models, simulations, and/or other techniques to predict the temperature for each AOI within the IC based on input that includes the sensor data, a known and/or simulated physical property of the IC, statistical information associated with the IC and/or testing of the IC, existing test results associated with the IC (e.g., from historical tests of the IC and/or earlier testing stages of the IC), test parameters associated with the test, manufacturing data associated with the IC, and/or other applicable information associated with the IC and/or test.

In step 508, execution engine 124 determines one or more control parameters based on the temperature prediction(s) and one or more control properties associated with the test instance. For example, execution engine 124 may use one or more machine learning models trained using steps 502 and 504 and/or other techniques to generate a target temperature, thermal control signal, command, and/or another type of value that can be used to control the operation of a thermal system that controls the temperature of the IC during the test instance and/or the operation of a test system that executes the test instance.

In step 510, execution engine 124 causes the test instance to be executed based on the control parameter(s). For example, execution engine 124 may transmit the control parameter(s) to the thermal system and/or test system and/or otherwise generate output that propagates the control parameter(s) to the thermal system and/or test system. The thermal system may use the control parameter(s) to control the temperature of the IC and/or individual portions of the IC (e.g., so that a target temperature is subsequently reached and/or maintained, a temperature limit is avoided, etc.). The test system may use the control parameter(s) to change the pacing of the test instance, pause the test instance, modify test steps performed in the test instance, and/or otherwise adjust the execution of the test instance. Execution engine 124 and/or management engine 126 may also, or instead, generate and/or log test results and/or other data related to the test instance based on the temperature prediction(s), control parameter(s), and/or other information collected and/or generated during the test instance.

In step 512, execution engine 124 determines whether or not execution of the test instance should continue. For example, execution engine 124 may determine that the test instance should continue to be executed until steps in the test have been performed, results of the test have been determined, a certain amount of time has passed, and/or another condition is met.

While execution engine 124 determines that execution of the test instance is to continue, execution engine 124 repeats steps 506, 508, and 510 to generate temperature predictions, control parameters, and/or other output that can be used to predict and/or regulate temperatures on the IC. Execution engine 124 also performs step 512 on a periodic and/or continuous basis to determine whether or not to continue executing the test instance.

Once execution engine 124 determines in step 512 that execution of the test instance should no longer be continued, management engine 126 performs step 514 to store temperature predictions, control parameters, and/or other thermal data generated during the test instance in one or more records associated with the test instance. For example, management engine 126 may store, in the record(s), mappings between the thermal data and one or more identifiers for the test instance and/or IC. The record(s) may then be stored in a data store; linked to additional data collected during other testing stages involving the IC; used to adjust subsequent thermal control and/or testing of the IC; used to generate and/or modify the design of packages and/or integrated systems that include the IC; and/or used to perform other tasks related to thermal regulation, testing, and/or IC design.

In sum, the disclosed techniques predict and regulate temperatures for various areas of interest (AOIs) within an IC during testing of the IC. Each AOI may include (but is not limited to) a two-dimensional (2D) and/or three-dimensional (3D) grid cell, functional block, arbitrarily shaped area, and/or another type of region or zone within the IC.

More specifically, the disclosed techniques use machine learning models, physics-based models, simulations, and/or other techniques to generate temperature predictions for each AOI within an IC based on sensor data, test parameters, and/or other inputs collected during testing of the IC. Each temperature prediction may represent a "real silicon temperature" at a corresponding AOI instead of temperatures measured by one or more temperature sensors that that are positioned outside of and/or at various distances from the AOI.

The temperature predictions are also used with the machine learning models, physics-based models, simulations, and/or other techniques to generate control parameters that are used to regulate the temperatures within the AOIs during testing of the IC. These control parameters may include (but are not limited to) target temperatures, thermal control signals for thermal systems, control signals that adjust the pace of testing, and/or control signals that start or stop testing operations. The control parameters may be determined based on the temperature predictions and/or control properties associated with the test, such as (but not limited to) temperature limits, temperature slopes, power slopes, safety offsets, and/or other values that characterize the progress and/or conditions of the test.

The temperature predictions and/or control parameters may be generated by an independent computing unit (e.g., computer-on-module (COM), single-board computer, etc.) that operates separately from and concurrently with a thermal system that performs thermal control of the IC suing the control parameters and a test system (e.g., automated test equipment (ATE), test program, etc.) that performs testing of the IC. This independent computing unit acts as an intermediate control point that decouples the test system and thermal system from one another while allowing the operation of each system to influence the operation of the other system. The independent computing unit also allows the thermal system, test system, and/or other components to access temperatures associated with the IC in an “on-demand” basis (e.g., without any “blind periods” in which the temperature sensors are not available).

Temperature prediction and control may additionally be performed across different stages of IC testing, such as (but not limited to) wafer sort testing, die-level testing, burn-in testing, final testing, and/or system-level testing. Data collected during earlier testing stages may be tracked and used to perform thermal prediction and control in later stages for the same IC. This data may also, or instead, be used to design, evaluate, and/or modify die layouts and/or packages involving the IC, test configurations for the tests, and/or other parameters associated with testing and/or using the IC.

One technical advantage of the disclosed techniques relative to the prior art is the ability to monitor and control temperatures at various AOIs within an IC in an accurate and timely manner. Consequently, the disclosed techniques may avoid and/or mitigate thermal damage and/or destruction that stem from limited monitoring of temperatures by temperature sensors and/or the inability to react quickly to sudden changes in heat generation during IC testing. Additionally, by incorporating thermal data collected during earlier testing stages into thermal prediction and regulation during subsequent testing stages involving the same IC, the disclosed techniques may improve the design and/or thermal management of complex ICs, packages, and/or integrated systems of multiple components with different thermal responses. These technical advantages provide one or more technological improvements over prior art approaches.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

CLAUSE 1. In various embodiments, a computer-implemented method for performing integrated circuit testing, comprises: generating one or more temperature predictions for an area of interest within an integrated circuit based on sensor data associated with the integrated circuit; determining, based on the one or more temperature predictions and one or more control properties associated with the integrated circuit, one or more control parameters associated with a test of the integrated circuit; and causing the test of the integrated circuit to be performed based on the one or more control parameters.

CLAUSE 2. The computer-implemented method of clause 1, further comprising: generating one or more additional temperature predictions and one or more additional control parameters based on a result of the test; and causing an additional test of the integrated circuit to be performed based on the one or more additional control parameters.

CLAUSE 3. The computer-implemented method of any of clauses 1 or 2, wherein the test is associated with a wafer or a die associated with the integrated circuit and the additional test is associated with a package associated with the integrated circuit.

CLAUSE 4. The computer-implemented method of any of clauses 1-3, wherein causing the test of the integrated circuit to be performed based on the one or more control parameters comprises controlling a temperature associated with the integrated circuit using the one or more control parameters.

CLAUSE 5. The computer-implemented method of any of clauses 1-4, wherein the one or more temperature predictions are generated by a first machine learning model and the one or more control parameters are generated by a second machine learning model.

CLAUSE 6. The computer-implemented method of any of clauses 1-5, wherein the one or more temperature predictions and the one or more control parameters are generated based on at least one of a machine learning model, a physics-based model, a control loop, a simulation, or an experiment.

CLAUSE 7. The computer-implemented method of any of clauses 1-6, wherein the one or more control parameters comprise at least one of a target temperature, a control signal for a thermal system associated with the test of the integrated circuit, a control signal associated with a pace of the test, or a control signal associated with starting or stopping the test.

CLAUSE 8. The computer-implemented method of any of clauses 1-7, wherein the one or more control properties comprise at least one of a temperature limit, a maximum deviation from a temperature limit, a minimum deviation from a temperature limit, a temperature slope, a temperature integral, a temperature deviation sum, a power slope, a safety offset, a distribution of power values, or one or more outlier values.

CLAUSE 9. The computer-implemented method of any of clauses 1-8, wherein the sensor data comprises at least one of a temperature, a power, an age, a current, a voltage, or a voltage drop.

CLAUSE 10. The computer-implemented method of any of clauses 1-9, wherein the one or more temperature predictions are further generated based on at least one of a physical property of the integrated circuit, statistical information associated with the integrated circuit, a test result associated with the integrated circuit, a test parameter associated with the test, or manufacturing data associated with the integrated circuit.

CLAUSE 11. In one or more embodiments, one or more non-transitory computer-readable media stores instructions that, when executed by one or more processors, cause the one or more processors to perform the steps of: generating one or more temperature predictions for an area of interest within an integrated circuit based on sensor data associated with the integrated circuit; determining, based on the one or more temperature predictions and one or more control properties associated with the integrated circuit, one or more control parameters associated with a test of the integrated circuit; and adjusting one or more thermal controls associated with the test based on the one or more control parameters.

CLAUSE 12. The one or more non-transitory computer-readable media of clause 11, wherein the instructions further cause the one or more processors to perform the steps of: determining (i) a set of ground truth temperatures associated with the area of interest and (ii) a set of ground truth control parameters associated with the integrated circuit; and training one or more machine learning models using the set of ground truth temperatures and the set of ground truth control parameters, wherein the one or more machine learning models are subsequently used to generate the one or more temperature predictions or the one or more control parameters.

CLAUSE 13. The one or more non-transitory computer-readable media of any of clauses 11-12, wherein training the one or more machine learning models comprises: generating, via execution of a machine learning model included in the one or more machine learning models, a predicted temperature for the area of interest based on input that includes training sensor data and training test program data associated with the integrated circuit; and training the machine learning model based on one or more losses computed using the predicted temperature and a corresponding ground truth temperature included in the set of ground truth temperatures.

14. The one or more non-transitory computer-readable media of any of clauses 11-13, wherein training the one or more machine learning models comprises: generating, via execution of a machine learning model included in the one or more machine learning models, a predicted control parameter based on input that includes a predicted temperature for the area of interest; and training the machine learning model based on one or more losses computed using the predicted control parameter and a corresponding ground truth control parameter included in the set of ground truth control parameters.

CLAUSE 15. The one or more non-transitory computer-readable media of any of clauses 11-14, wherein the instructions further cause the one or more processors to perform the steps of: generating one or more additional temperature predictions and one or more additional control parameters based on the one or more temperature predictions and the one or more control parameters; and adjusting the one or more thermal controls based on the one or more additional control parameters.

CLAUSE 16. The one or more non-transitory computer-readable media of any of clauses 11-15, wherein the one or more thermal controls are adjusted during the test or a subsequent test of the integrated circuit.

CLAUSE 17. The one or more non-transitory computer-readable media of any of clauses 11-16, wherein the one or more temperature predictions and the one or more control parameters are generated based on at least one of a machine learning model, a physics-based model, a control loop, a simulation, or an experiment.

CLAUSE 18. The one or more non-transitory computer-readable media of any of clauses 11-17, wherein the sensor data is collected by one or more sensors that are positioned outside of the area of interest.

CLAUSE 19. The one or more non-transitory computer-readable media of any of clauses 11-18, wherein the area of interest comprises a two-dimensional or three-dimensional region within the integrated circuit.

CLAUSE 20. In one or more embodiments, a system comprises: one or more memories that store instructions, and one or more processors that are coupled to the one or more memories and, when executing the instructions, are configured to perform the steps of: generating one or more temperature predictions for an area of interest within an integrated circuit based on sensor data associated with one or more locations in the integrated circuit that are outside of the area of interest; determining, based on the one or more temperature predictions and one or more control properties associated with the integrated circuit, one or more control parameters associated with a test of the integrated circuit; and causing the test of the integrated circuit to be performed based on the one or more control parameters.

Any and all combinations of any of the claim elements recited in any of the claims and/or any elements described in this application, in any fashion, fall within the contemplated scope of the embodiments and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for performing integrated circuit testing, comprising:
generating one or more temperature predictions for an area of interest within an integrated circuit based on sensor data associated with the integrated circuit;
determining, based on the one or more temperature predictions and one or more control properties associated with the integrated circuit, one or more control parameters associated with a test of the integrated circuit; and
causing the test of the integrated circuit to be performed based on the one or more control parameters.

2. The computer-implemented method of claim 1, further comprising:
generating one or more additional temperature predictions and one or more additional control parameters based on a result of the test; and
causing an additional test of the integrated circuit to be performed based on the one or more additional control parameters.

3. The computer-implemented method of claim 2, wherein the test is associated with a wafer or a die associated with the integrated circuit and the additional test is associated with a package associated with the integrated circuit.

4. The computer-implemented method of claim 1, wherein causing the test of the integrated circuit to be performed based on the one or more control parameters comprises controlling a temperature associated with the integrated circuit using the one or more control parameters.

5. The computer-implemented method of claim 1, wherein the one or more temperature predictions are generated by a first machine learning model and the one or more control parameters are generated by a second machine learning model.

6. The computer-implemented method of claim 1, wherein the one or more temperature predictions and the one or more control parameters are generated based on at least one of a machine learning model, a physics-based model, a control loop, a simulation, or an experiment.

7. The computer-implemented method of claim 1, wherein the one or more control parameters comprise at least one of a target temperature, a control signal for a thermal system associated with the test of the integrated circuit, a control signal associated with a pace of the test, or a control signal associated with starting or stopping the test.

8. The computer-implemented method of claim 1, wherein the one or more control properties comprise at least one of a temperature limit, a maximum deviation from a temperature limit, a minimum deviation from a temperature limit, a temperature slope, a temperature integral, a temperature deviation sum, a power slope, a safety offset, a distribution of power values, or one or more outlier values.

9. The computer-implemented method of claim 1, wherein the sensor data comprises at least one of a temperature, a power, an age, a current, a voltage, or a voltage drop.

10. The computer-implemented method of claim 1, wherein the one or more temperature predictions are further generated based on at least one of a physical property of the integrated circuit, statistical information associated with the integrated circuit, a test result associated with the integrated circuit, a test parameter associated with the test, or manufacturing data associated with the integrated circuit.

11. One or more non-transitory computer-readable media storing instructions that, when executed by one or more processors, cause the one or more processors to perform the steps of:
generating one or more temperature predictions for an area of interest within an integrated circuit based on sensor data associated with the integrated circuit;
determining, based on the one or more temperature predictions and one or more control properties associated with the integrated circuit, one or more control parameters associated with a test of the integrated circuit; and
adjusting one or more thermal controls associated with the test based on the one or more control parameters.

12. The one or more non-transitory computer-readable media of claim 11, wherein the instructions further cause the one or more processors to perform the steps of:
determining (i) a set of ground truth temperatures associated with the area of interest and (ii) a set of ground truth control parameters associated with the integrated circuit; and
training one or more machine learning models using the set of ground truth temperatures and the set of ground truth control parameters, wherein the one or more machine learning models are subsequently used to generate the one or more temperature predictions or the one or more control parameters.

13. The one or more non-transitory computer-readable media of claim 12, wherein training the one or more machine learning models comprises:
generating, via execution of a machine learning model included in the one or more machine learning models, a predicted temperature for the area of interest based on input that includes training sensor data and training test program data associated with the integrated circuit; and
training the machine learning model based on one or more losses computed using the predicted temperature and a corresponding ground truth temperature included in the set of ground truth temperatures.

14. The one or more non-transitory computer-readable media of claim 12, wherein training the one or more machine learning models comprises:
generating, via execution of a machine learning model included in the one or more machine learning models, a predicted control parameter based on input that includes a predicted temperature for the area of interest; and
training the machine learning model based on one or more losses computed using the predicted control parameter and a corresponding ground truth control parameter included in the set of ground truth control parameters.

15. The one or more non-transitory computer-readable media of claim 11, wherein the instructions further cause the one or more processors to perform the steps of:
generating one or more additional temperature predictions and one or more additional control parameters based on the one or more temperature predictions and the one or more control parameters; and
adjusting the one or more thermal controls based on the one or more additional control parameters.

16. The one or more non-transitory computer-readable media of claim 15, wherein the one or more thermal controls are adjusted during the test or a subsequent test of the integrated circuit.

17. The one or more non-transitory computer-readable media of claim 11, wherein the one or more temperature predictions and the one or more control parameters are generated based on at least one of a machine learning model, a physics-based model, a control loop, a simulation, or an experiment.

18. The one or more non-transitory computer-readable media of claim 11, wherein the sensor data is collected by one or more sensors that are positioned outside of the area of interest.

19. The one or more non-transitory computer-readable media of claim 11, wherein the area of interest comprises a two-dimensional or three-dimensional region within the integrated circuit.

20. A system, comprising:
one or more memories that store instructions, and
one or more processors that are coupled to the one or more memories and, when executing the instructions, are configured to perform the steps of:
generating one or more temperature predictions for an area of interest within an integrated circuit based on sensor data associated with one or more locations in the integrated circuit that are outside of the area of interest;
determining, based on the one or more temperature predictions and one or more control properties associated with the integrated circuit, one or more control parameters associated with a test of the integrated circuit; and
causing the test of the integrated circuit to be performed based on the one or more control parameters.
